(19) United States
(12) Patent Application Publication
(10) Pub. No.: US 2024/0222390 A1
(43) Pub. Date: Jul. 4, 2024

(54) DISPLAY PANEL AND METHOD FOR MANUFACTURING DISPLAY PANEL

(71) Applicant: Guangzhou China Star Optoelectronics Semiconductor Display Technology Co., Ltd., Guangzhou (CN)

(72) Inventor: Cheng GONG, Guangzhou (CN)

(73) Assignee: Guangzhou China Star Optoelectronics Semiconductor Display Technology Co., Ltd., Guangzhou (CN)

(21) Appl. No.: 18/519,107

(22) Filed: Nov. 27, 2023

(30) Foreign Application Priority Data
Dec. 29, 2022 (CN) 202211714645.2

(51) Int. Cl. H01L 27/12

(52) U.S. Cl. CPC H01L 27/124; H01L 27/1222; H01L 27/127

(57) ABSTRACT

The embodiment of the application provides a display panel and a method for manufacturing display panel. The display panel includes a substrate, a source drain metal layer, a gate, and an active layer; wherein the source drain metal layer includes at least one source and at least one drain, the source is disposed between two adjacent drains, or the drain is disposed between two adjacent sources, and the active layer is disposed between and electrically connected to the source and the drain.

### CROSS-REFERENCE TO RELATED APPLICATION

This application claims priority to Chinese Patent Application No. 202211714645.2, filed on Dec. 29, 2022, which is hereby incorporated by reference in its entirety.

### TECHNICAL FIELD

The present application relates to the technical field of manufacturing a display panel, and more particularly, to a display panel and a method for manufacturing a display panel.

### BACKGROUND

With development on manufacturing technology of display panels, the display effect and the comprehensive performance of the display panel are highly required.

In manufacturing display panels, it is generally desirable to form an array substrate for a plurality of thin film transistors within the array substrate. When the display panel operates normally, different thin film transistors provide corresponding driving control signals to the display panel, to ensure normal operation of the display panel. Therefore, the thin film transistor in the array substrate has a great influence on the display performance. In related art, when forming a thin film transistor, multiple different photomasks and etching processes are generally needed, however, the etching process may cause damage to an oxide semiconductor layer in the thin film transistor. As a result, a driving current in the thin film transistor is reduced, the performance of the thin film transistor is further reduced, and finally the performance of the display panel is affected, which is unfavorable for further improvement of overall performance of the display panel.

In view of the above, in conventional forming of the thin film transistor in the display panel, it is easy to cause etching damage to the oxide semiconductor layer, thereby reducing the driving current in the thin film transistor, and further affecting the overall performance of the display panel.

### TECHNICAL SOLUTION

An embodiment of the present application provides a display panel and a method for manufacturing display panel so as to effectively improve a problem that an oxide semiconductor layer is easily damaged during manufacturing the display panel, and to improve a driving current of a thin film transistor.

To solve the above technical problems, an embodiment of the present application provides a display panel, wherein the display panel includes:
a substrate;
a source drain metal layer disposed on the substrate, wherein the source drain metal layer comprises at least one source and at least one drain, the source is disposed between two adjacent drains or the drain is disposed between two adjacent sources;
an active layer, wherein the active layer is disposed between and is electrically connected to the drain and the source adjacent to the drain; and
a gate disposed on and insulated from the source drain metal layer.

According to an embodiment of the present application, the source includes a first source and a second source;
wherein the first source, the second source, and the drain are provided in a same layer; the active layer is provided between the first source and the drain, and between the second source and the drain; and the active layer electrically connected to the first source, the second drain, and the drain.

According to an embodiment of the present application, a first space is defined between the first source and the drain, a second space is defined between the second source and the drain, and the first space has a length same as the second space.

According to an embodiment of the present application, the first source, the second source, and the drain have a same thickness.

According to an embodiment of the present application, a width of the drain is less than a width of the first source and a length of the second source, and the width of the first source is equal to the width of the second source.

According to an embodiment of the present application, the display panel further includes a passivation layer and a pixel electrode;
wherein the passivation layer is disposed on the gate and covers a part of the source drain metal layer and the gate, and the pixel electrode is disposed on the passivation layer and electrically connected to the source through a via.

According to an embodiment of the present application, the pixel electrode is electrically connected to the first source through a first via, and connected to the second source through a second via.

According to an embodiment of the present application, the drain comprises a first drain and a second drain;
wherein the source is disposed between the first drain and the second drain, the active layer is provided between the first drain and the source, and between the second drain and the source.

According to an embodiment of the present application, an orthographic projection of the gate on the substrate covers the active layer.

According to an embodiment of the present application, a length of the source is less than a length of the first drain and a length of the second drain, and the length of the first drain is equal to the length of the second drain.

According to a second aspect of the embodiments of the present application, a method of manufacturing display panel is provided, wherein the method includes:
providing a substrate, depositing a source drain metal layer on the substrate, and patterning the source drain metal layer;
depositing an active layer on the substrate at a position in the source drain metal layer;
depositing a gate insulating layer on the source drain metal layer, depositing a gate on the gate insulating layer, and patterning the gate insulating layer and the gate;
depositing a passivation layer on the substrate, and etching a via on the passivation layer; and
depositing a pixel electrode on the passivation layer, wherein the pixel electrode is electrically connected to the source drain metal layer through the via.

Advantageous of embodiments of the present application: compared with related art, the embodiments of the present application provide a display panel and a method for preparing display panel. The display panel includes a substrate, a source drain metal layer, a gate, and an active layer; wherein the source drain metal layer includes at least one source and at least one drain, the source is disposed between two adjacent drains, or the drain is disposed between two adjacent sources, and the active layer is disposed between and is electrically connected to the source and the drain. In embodiments of the present application, a patterned source drain metal layer is directly prepared on the substrate, while the active layer is disposed between adjacent source and drain, and the pixel electrode connects the sources or the drains on both sides in series to form a double-thin-film-transistor structure. As such, a driving current in the thin film transistor is effectively improved. At the same time, since the active layer and the source drain metal layer are disposed in a same layer, and the active layer is disposed at a patterned position in the source drain metal layer, the active layer is less etched during manufacturing, and the comprehensive performance of the display panel is effectively improved.

### BRIEF DESCRIPTION OF THE DRAWINGS

In order that the technical solution in the embodiments of the present application may be explained more clearly, reference is now being made briefly to the accompanying drawings required for description. It should be understood that the accompanying drawings in the following description are merely some of the embodiments of the present application, and other drawings may be made to those skilled in the art without involving any inventive effort.

FIG. 1 is a schematic diagram of a film structure of a display panel according to an embodiment of the present application;

FIG. 2 is a wiring diagram corresponding to a thin film transistor in a display panel according to an embodiment of the present application;

FIG. 3 is a method for manufacturing a display panel according to an embodiment of the present application; and

FIGS. 4 to 8 are schematic diagrams of film structures corresponding to a process for manufacturing a display panel according to an embodiment of the present application.

### DETAILED DESCRIPTION OF THE EMBODIMENTS

The following disclosure, taken in conjunction with the accompanying drawings in which embodiments of the application are described, provides different embodiments or examples to implement different structures of the application. In order to simplify the present application, components and arrangements of embodiments are described below. Furthermore, the various specific processes and examples of materials provided by the present application will be appreciated by those of ordinary skill in the art of other process applications. All other embodiments obtained by those skilled in the art without inventive effort are in the scope of the present application.

With development on manufacturing technology of display panels, the display effect and the comprehensive performance of the display panel and the display device are highly required.

The performance of the display panel is affected by the thin film transistor in the display panel. In related art, when forming the thin film transistor structure, multiple light etching processes are generally performed. In the etching process, the thin film layers are affected, for example, the etching process may cause damage to an oxide semiconductor layer. As a result, a driving current in the thin film transistor is reduced, which is unfavorable for further improvement of overall performance of the display panel.

Embodiments of the present application provide a display panel and a method for manufacturing a display panel to improve the manufacturing process, and to improve the structure of the thin film transistor. Thus, the damage to the thin film transistor in the manufacturing process is effectively avoided, and the performance of the whole display panel is improved.

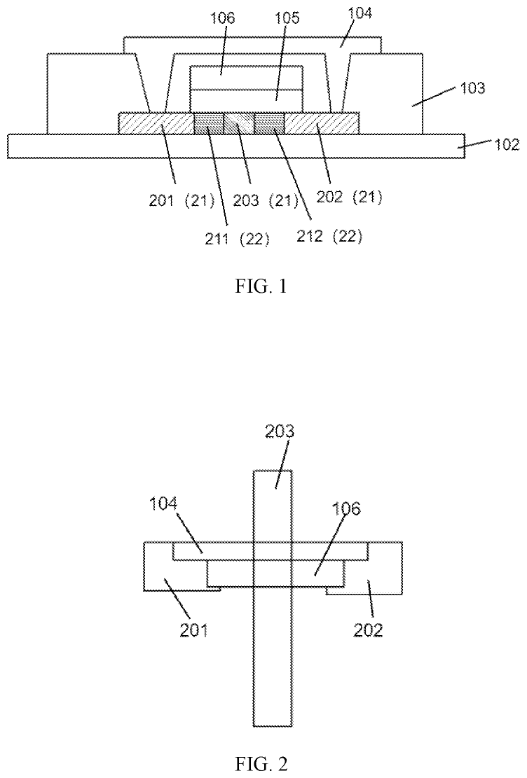

As shown in FIG. 1, FIG. 1 is a schematic diagram of a film structure of a display panel according to an embodiment of the present application. In an embodiment of the present application, the display panel includes an array substrate, wherein the array substrate is a thin film transistor array substrate. Specifically, the display panel may include a substrate 102 and a thin film transistor structure disposed on the substrate 102.

Specifically, an active layer 22 and a source drain metal layer 21 are provided, wherein the active layer 22 and the source drain metal layer 21 are both provided on the substrate 102, and the active layer 22 and the source drain metal layer 21 may be provided in the same layer.

Further, the source drain metal layer 21 is patterned on the substrate 102, wherein the source drain metal layer 21 may include at least one source and at least one drain. The source drain metal layer 21 thus forms a plurality of segmented structures on the substrate 102. Alternatively, the source is disposed between two adjacent drains, or the drain is disposed between two adjacent sources. At the same time, a space is provided between the source and the drain adjacent to the source, to finally form the patterned source drain metal layer 21 provided in the embodiment of the present application.

In an embodiment of the present application, the active layer 22 is disposed in the space between the source and the drain adjacent to the source, so that the active layer 22 is disposed in the same layer as the source drain metal layer 21. The active layer 22 is electrically connected to the source and the drain.

Further, in the following example, the source drain metal layer 21 in the embodiment of the present application is provided with the example where the drain is disposed between the two adjacent sources. Alternatively, the source may be disposed between the two drains, and details are not described herein. When the source and the drain positions are switched, the manufacturing process is the same with the example where the drain is disposed between the two adjacent sources and example where the source is disposed between the two adjacent drains.

Specifically, the source includes a first source 201 and a second source 202. The drain 203 is provided between the first source 201 and the second source 202. A first space is provided between the drain 203 and the first source 201, and a second space is provided between the drain 203 and the second source 202.

In an embodiment of the present application, a length of the first space provided between the drain 203 and the first source 201 is same as a length of the second space provided between the drain 203 and the second source 202. In this way, the drain 203 has same distances from adjacent sources, thereby ensuring the stability and consistency of the performance of the thin film transistor.

Meanwhile, the active layer includes a first active layer 211 and a second active layer 212. In an embodiment of the present application, the active layer 22 is disposed in the space between the drain and the source adjacent to the drain. Specifically, the first active layer 211 is disposed in the first space between the first source 201 and the drain 203, and the second active layer 212 is disposed in the second space between the second source 202 and the drain 203. Meanwhile, an end of the first active layer 211 is electrically connected to the first source 201, and the other end of the first active layer 211 is electrically connected to the drain 203.

Further, an end of the second active layer is electrically connected to the drain 203, and the other end of the second active layer 212 is electrically connected to the second source 202, thereby finally forming a structure in which the source drain metal layer and the active layer are spaced in embodiments of the present application. As such, no damage is caused to the active layer during etching different film layers to form the above structure, which effectively ensures the performance of the thin film transistor.

In an embodiment of the present application, the active layer and the source drain metal layer are provided as above, the first source 201 and the second source 201 are provided in same layer as the first active layer 211 and the second active layer 212, and the first source 201 and the second source 201 have same thickness as the first active layer 211 and the second active layer 212. In an embodiment, a thickness of the first source 201, a thickness of the second source 201, a thickness of the first active layer 211, and a thickness of the second active layer 212 may range from 400 Å to 800 Å. In the present embodiment, the above thickness may be 400 Å, 500 Å, 700 Å, 800 Å or other parameter values, and details are not described herein. In embodiment of the present application, the active layer and the source drain metal layer are arranged in the same layer, and the active layer is correspondingly arranged at the patterned structures of the source drain metal layer, thereby effectively reducing damage to the active layer in the manufacturing process and effectively improving the comprehensive performance of the display panel.

Further, in the embodiment of the present application, to ensure that the thin film transistor has a high driving current and other properties, the length of the first source 201 may be the same as the length of the second source 202 during providing the functional thin film layers as above. Specifically, the lengths of the first source 201 and the second source 202 may range 8 um to 12 um. Alternatively, the lengths of the first source 201 and the second source 202 may be 9 um, 11 um, or 12 um, which may be set according to different products, and are not limited herein.

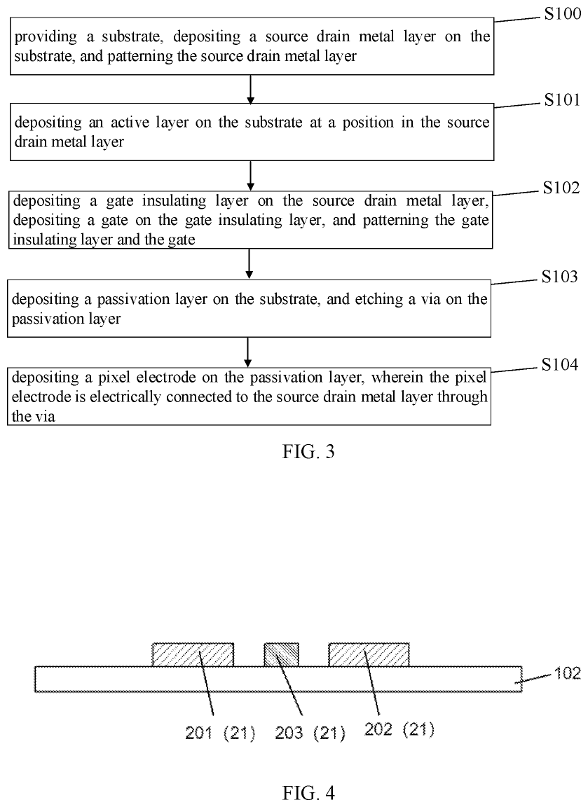

Meanwhile, in the present embodiment, during preparing the drain 203, the first space between the drain 203 and the first source 201 has same distance as the second space between the drain 203 and the second source 202. Specifically, the first space and the second space may range from 5 um to 7 um. In an embodiment, the distance between the drain 203 and the first source 201, and the distance between the drain 203 and the second source 202 may be 5 um, 6 um, or 7 um. Specifically, the distance may be set according to different product sizes, and details are not described herein. As shown in FIG. 2, a width of the drain 203 is less than a width of the first source 201 and a width of the second source 202, and the width of the first source 201 is equal to the width of the second source 202. Further, the width of the drain 203 may range from 4 um to 7 um.

Further, in the embodiment of the present application, the first active layer 211 is provided in the first space, and the second active layer 212 is provided in the second space. Since the first space and the second space have same distance, the lengths of the first active layer 211 and the second active layer 212 are same.

Further, the length of the first source 201 and the length of the second source 202 are both greater than the length of the drain 203 disposed between the first source 201 and the second source 202. In an embodiment, the first source 201 and the second source 202 may be provided symmetrically with respect to the drain 203.

In an embodiment of the present application, the display panel further includes a gate insulating layer 105, a gate 106, and a passivation layer 103.

Specifically, the gate insulating layer 105 is provided on the source drain metal layer 21 and the active layer 22, and the gate 106 is provided on the gate insulating layer 105; while the gate 106 and the gate insulating layer 105 completely cover the drain 203 and the active layer 22, and the gate insulating layer 105 at least partially covers the first source 201 and the second source 202. Thus, it is ensured that during the etching process, the gate insulating layer 105 and the gate 106 can be formed in one step by a corresponding mask, and different film layers are protected.

In an embodiment of the present application, the passivation layer 103 is disposed on the substrate 102, and the passivation layer 103 completely covers the gate 106, and covers a part of the first source 201 and the second source 202. Thus, different film layers are protected by the passivation layer 103.

Further, a via may be provided on the passivation layer 103 at a portion covering the first source 201 and/or at a portion covering the second source 202. For example, the via may be provided close to an edge of the first source 201 and/or close to an edge of the second source 202.

Further, the display panel further includes a pixel electrode 104. In an embodiment of the present application, the pixel electrode 104 is disposed on the passivation layer 103, and the pixel electrode 104 is electrically connected to the first source 201 and the second source 202 through the corresponding via. When the display panel is normally operated, a control signal is transmitted to the pixel electrode 104 through the thin film transistor, and the normal operation of the thin film transistor device is ensured. In an embodiment of the present application, the material of the pixel electrode 104 may be indium tin oxide. Other conductive materials can be used according to different properties. Meanwhile, in an embodiment of the present application, the pixel electrode 104 connects the first source 201 and the second source 202 in series, so that the first source 201 and the drain 203 can define a first thin film transistor, and the second source 202 and the drain 203 can define a second thin film transistor different from the first thin film transistor. As such, and the first thin film transistor and the second thin film transistor combine to increase the driving current in the device, thereby improving the charge rate and the performance of the whole display panel.

As shown in FIG. 2, FIG. 2 is a wiring diagram corresponding to a thin film transistor in a display panel according to an embodiment of the present application. Combined with FIG. 1, in the embodiment of the present application, the drain 203 is disposed between the first source 201 and the second source 202, and the first space between the drain 203 and the first source 201 has a same distance with the second space between the drain 203 and the second source 202. Meanwhile, the gate 106 and the pixel electrode 104 are provided on the film layers between the first source 201 and the second source 202, and are insulated from the same.

Further, referring to the structure shown in FIG. 1, the position of the source and the position of the drain may be interchanged.

For example, the drain may include a first drain and a second drain, and the source is disposed between the first drain and the second drain. At this time, the active layer is correspondingly provided between the first drain and the source, and between the second drain and the source. Further, the orthographic projection of the gate on the substrate covers the active layer. Thus, the position of the source and the position of the drain can be interchanged to meet the use requirements of different products, and the performance thereof is effectively improved.

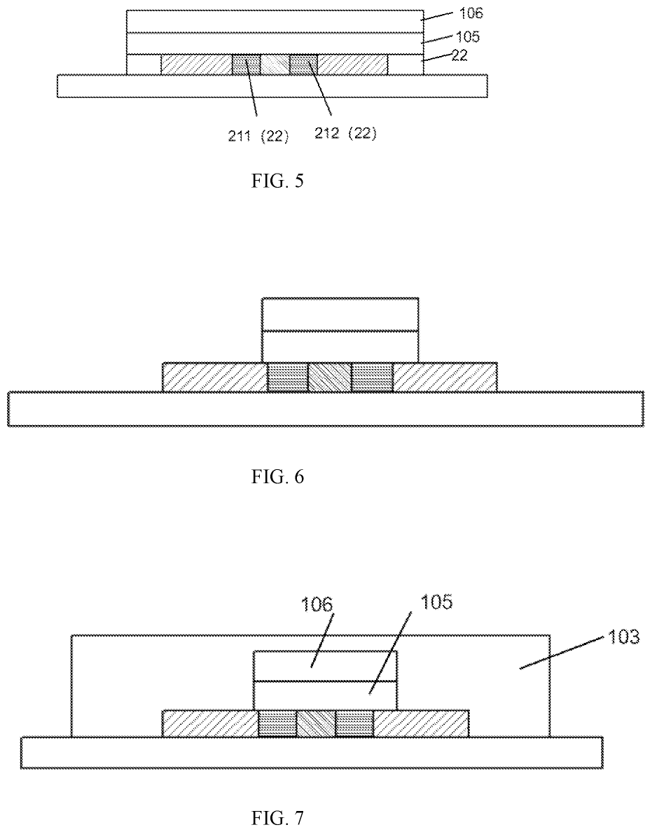

As shown in FIG. 3, FIG. 3 is a method for manufacturing a display panel according to an embodiment of the present application, wherein the method includes the following:
S100: providing a substrate, depositing a source drain metal layer on the substrate, and patterning the source drain metal layer;
S101: depositing an active layer on the substrate at a position in the source drain metal layer;
S102: depositing a gate insulating layer on the source drain metal layer, depositing a gate on the gate insulating layer, and patterning the gate insulating layer and the gate;
S103: depositing a passivation layer on the substrate, and etching a via on the passivation layer; and
S104: depositing a pixel electrode on the passivation layer, wherein the pixel electrode is electrically connected to the source drain metal layer through the via.

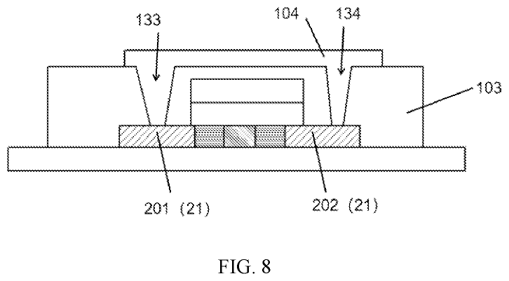

Specifically, reference is made to FIGS. 4 to 8. FIGS. 4 to 8 are schematic diagrams of film structures corresponding to a process for manufacturing a display panel according to an embodiment of the present application. Referring to FIG. 4, during manufacturing a display panel provided in embodiments of the present application, a substrate 102 is first provided, and a second metal layer is deposited on the substrate 102. In an embodiment of the present application, the second metal layer is a source drain metal layer 21. After the deposition of the source drain metal layer 21, the source drain metal layer 21 is patterned.

Specifically, the source drain metal layer 21 is etched to form a first source 201, a second source 202, and a drain 203. The first source 201 and the second source 202 are different sides of the drain 203. The position between first source 201 and the drain 203 are etched to define a first space, and the position between the second source 202 and the drain 203 are etched to define a second space.

In an embodiment of the present application, the first space between the drain 203 and the first source 201 has a same distance with the second space between the drain 203 and the second source 202. As such, the thin film transistor is stably operated, and a high driving current is ensured to be provided by the thin film transistor.

Referring to FIG. 5, after the patterning of the source drain metal layer 21 is completed, an active layer 22 is deposited on the substrate 102. Specifically, the active layer 22 is deposited in the same layer as the source drain metal layer 21, for example, filled in the first space between the first source 201 and the drain 203, the second space between the second source 202 and the drain 203, and in other regions on sides of the first source 201 and the second source 202.

After the active layer 22 is deposited, a gate insulating layer 105 is deposited on the active layer 22 and the source drain metal layer 21, and a gate 106 is deposited continuously on the gate insulating layer 105.

As shown in FIG. 6, after the gate and the gate insulating layer are prepared, a photomask patterning and etching process is performed. When etching is performed, the gate insulating layer and the active layer are respectively subjected to a photomask process with the gate 106 as a reference, and a desired structure is formed by etching. In desired structure, the gate insulating layer 105 covers at least a part of the first source 201 and at least a part of the second source 202, while the gate insulating layer 105 covers the drain 203. In an embodiment of the present application, the gate insulating layer 105 may be symmetrically disposed with respect to the drain 203. Meanwhile, the portion of the gate insulating layer 105 extended on the second source 202 may have a length ranging from 2 um to 3 um.

As shown in FIG. 7, after the etching for the gate 106, the gate insulating layer 105, and the active layer, a passivation layer 103 is deposited on the substrate 102. Specifically, the passivation layer 103 completely covers the gate 106, the first source, and the second source. As such, the film layers are protected by the passivation layer 103. In embodiments of the present application, the thickness of the passivation layer 103 may be greater than the sum of the thickness of the film layers of the source drain metal layer, the gate and gate insulating layer. Therefore, the protection effect of the passivation layer is ensured.

As shown in FIG. 8, the passivation layer 103 is etched at a position covering the first source 201 and a position covering the second source 202, to form a via.

Specifically, a first via is formed on the position of the passivation layer 103 covering the first source 201, a second via 134 is formed on the position of the passivation layer 103 covering the second source 202. The surface of the first source 201 corresponding to the first via 133 and the surface of the second source 202 corresponding to the second via 134 are exposed.

After the first via 133 and the second via 134 are etched, a pixel electrode 104 is deposited on the passivation layer 103. In the present embodiment, the pixel electrode 104 is filled with the first via 133 and the second via 134. In this way, the pixel electrode 104 is electrically connected to the active layer through the via, and the first source 201 and the second source 202 are connected in series. The first source 201 and the drain 203 define a first thin film transistor, and the second source 202 and the drain 203 define a second thin film transistor. Thus, the first thin film transistor and the second thin film transistor are connected in series to increase the driving current and the driving capability of the thin film transistor effectively, while providing a control signal through the thin film transistor.

Further, after the pixel electrode 104 and the corresponding film layers are disposed, other film layers may be prepared continuously on the passivation layer 103 and the pixel electrode 104. The other film layers may be the touch control layer, and the encapsulation layer, which is not described here.

In embodiments of the present application, the structure of the thin film transistor corresponding to the display panel is formed by only four photomask processing. Meanwhile, during the photomask etching process, no damage is caused to the film layer, such as the active layer, in the thin film transistor, thereby effectively protecting the thin film transistor and reducing the complexity of the manufacture thereof.

Further, an embodiment of the present application further provides a display device including the display panel provided in embodiments of the present application, wherein the thin film transistor in the display panel has a simple manufacturing process and has a high driving current, thereby effectively improving the comprehensive performance of the display panel.

In the embodiment of the present application, in addition to three-segment structure defined by the first source, the second source, and the drain, multiple-segment structure can be provided according to the requirements and performance of different products, and the active layer is correspondingly provided in the space between the drain and the source adjacent to the drain, thereby effectively simplifying the preparation process and improving the comprehensive performance of the display panel.

In embodiments of the present application, the display panel and the display device may be any display-capable or touch-operable product or component such as a mobile phone, a computer, an electronic paper, a display, a notebook computer, or a digital photo frame, a type of which is not specifically limited.

In view of the foregoing, the present application is described in detail with reference to a method for manufacturing a display panel and a display panel according to an embodiment of the present application, and the principles and embodiments of the present application are described with reference to specific examples. The description of the above embodiments is merely intended to help understand the technical solution and the core idea of the present application. Although the present application is described in terms of the embodiments, the embodiments are not intended to limit the present application. Those skilled in the art will be able to make various changes and modifications without departing from the spirit and scope of the present application.

1. A display panel, comprising:
a substrate;
a source drain metal layer disposed on the substrate, wherein the source drain metal layer comprises at least one source and at least one drain, the source is disposed between two adjacent drains or the drain is disposed between two adjacent sources;
an active layer, wherein the active layer is disposed between and is electrically connected to the drain and the source adjacent to the drain; and
a gate disposed on and insulated from the source drain metal layer.

2. The display panel according to claim 1, wherein the source comprises a first source and a second source;
wherein the first source, the second source, and the drain are provided in a same layer; the active layer is provided between the first source and the drain, and between the second source and the drain; and the active layer electrically connected to the first source, the second drain, and the drain.

3. The display panel of claim 2, wherein a first space is defined between the first source and the drain, a second space is defined between the second source and the drain, and the first space has a length same as the second space.

4. The display panel of claim 2, wherein the first source, the second source, and the drain have a same thickness.

5. The display panel of claim 2, wherein a width of the drain is less than a width of the first source and a width of the second source, and the width of the first source is equal to the width of the second source.

6. The display panel of claim 2, further comprising a passivation layer and a pixel electrode;
wherein the passivation layer is disposed on the gate and covers a part of the source drain metal layer and the gate, and the pixel electrode is disposed on the passivation layer and electrically connected to the source through a via.

7. The display panel of claim 6, wherein the pixel electrode is electrically connected to the first source through a first via, and connected to the second source through a second via.

8. The display panel of claim 1, wherein an orthographic projection of the gate on the substrate covers the active layer.

9. The display panel of claim 2, wherein a length of the drain is less than a length of the first source and a length of the second source, and the length of the first source is equal to the length of the second source.

10. The display panel of claim 1, wherein the drain comprises a first drain and a second drain;
wherein the source is disposed between the first drain and the second drain, the active layer is provided between the first drain and the source, and between the second drain and the source.

11. The display panel of claim 10, wherein an orthographic projection of the gate on the substrate covers the active layer.

12. The display panel of claim 10, wherein a length of the source is less than a length of the first drain and a length of the second drain, and the length of the first drain is equal to the length of the second drain.

13. A method of manufacturing display panel, comprising:
providing a substrate, depositing a source drain metal layer on the substrate, and patterning the source drain metal layer;
depositing an active layer on the substrate at a position in the source drain metal layer;
depositing a gate insulating layer on the source drain metal layer, depositing a gate on the gate insulating layer, and patterning the gate insulating layer and the gate;
depositing a passivation layer on the substrate, and etching a via on the passivation layer; and
depositing a pixel electrode on the passivation layer, wherein the pixel electrode is electrically connected to the source drain metal layer through the via.

14. The method of claim 13, wherein the patterning the source drain metal layer comprises:
etching the source drain metal layer to form a first source, a second source, and a drain; wherein the drain is disposed between the first source and the second source, a first space is defined between the first source and the drain, and a second space is defined between the second source and the drain.

15. The method of claim 14, wherein the depositing the active layer on the substrate at the position in the source drain metal layer comprises:
depositing the active layer in the first space and the second space.

16. The method of claim 15, wherein the patterning the gate insulating layer and the gate comprises:
etching the gate insulating layer and the gate to form that the gate insulating layer and the gate cover at least a part of the first source, the drain, and at least a part of the second source.

17. The method of claim 16, wherein the etching the via on the passivation layer comprises:
etching a first via on a position of the passivation layer covering the first source; and
etching a second via on a position of the passivation layer covering the second source.

18. The method of claim 17, wherein the pixel electrode disposed on the passivation layer is electrically connected to the first source through the first via, and is electrically connected to the second source through the second via.
